(19) United States
(12) Patent Application Publication
(10) Pub. No.: US 2026/0259502 A1
(43) Pub. Date: Sep. 3, 2026

(54) RESIST UNDERLAYER FILM-FORMING COMPOSITION CONTAINING POLYCYCLIC AROMATIC-CONTAINING POLYMER

(71) Applicant: NISSAN CHEMICAL CORPORATION, Tokyo (JP)

(72) Inventors: Ryuta MIZUOCHI, Toyama-shi (JP); Hiroto OGATA, Toyama-shi (JP); Mamoru TAMURA, Toyama-shi (JP)

(73) Assignee: NISSAN CHEMICAL CORPORATION, Tokyo (JP)

(21) Appl. No.: 18/716,066

(22) PCT Filed: Dec. 8, 2022
(86) PCT No.: PCT/JP2022/045268

§ 371 Date: Jun. 3, 2024

(30) Foreign Application Priority Data
Dec. 9, 2021 (JP) 2021-200330

(51) Int. Cl. G03F 7/11; G03F 7/16; G03F 7/20; H10P 50/00; H10P 50/24

(52) U.S. Cl. CPC G03F 7/11; G03F 7/168; G03F 7/2004; G03F 7/2059; H10P 50/242; H10P 50/246; H10P 50/692; H10P 50/695

(57) ABSTRACT

A resist underlayer film which is a baked product of a coating film of a resist underlayer film-forming composition, the resist underlayer film-forming composition containing a polymer having at least one unit structure of a unit structure (A) having a polycyclic aromatic hydrocarbon structure and a unit structure (B) derived from a maleimide structure, and the resist underlayer film having a film thickness of less than 10 nm.

### TECHNICAL FIELD

The present invention relates to a resist underlayer film, a resist underlayer film-forming composition for EB or EUV lithography, a semiconductor processing substrate, a method for producing a semiconductor element, a pattern forming method, and a method for improving the LWR of a resist pattern.

### BACKGROUND ART

In semiconductor devices such as an LSI (semiconductor integrated circuit), formation of a fine pattern is required with improvement in integration, and a minimum pattern size in recent years has reached 100 nm or less.

Formation of such a fine pattern in semiconductor devices has been realized by shortening of the wavelength of a light source in an exposure apparatus and improvement in a resist material. At present, an immersion exposure method in which exposure is performed using an ArF (argon fluoride) excimer laser beam having a wavelength of 193 nm, which is deep ultraviolet light, as a light source through water is performed, and various ArF resist materials containing an acrylic resin as a base have also been developed as resist materials.

Moreover, as an exposure technology of next-generation, an electron beam (EB) exposure method using an electron beam or an extreme ultraviolet (EUV) exposure method using a soft X-ray having a wavelength of 13.5 nm as a light source has been studied, and the pattern size is 30 nm or less, and therefore further miniaturization has been advanced.

However, along with such miniaturization of the pattern size, roughness on the side surface of the resist pattern (LER; line edge roughness) and unevenness of the resist pattern width (LWR: line width roughness) are increased, which brings concerns that these defects may adversely affect performances of the device. Studies have been made to suppress these defects by, for example, optimization of an exposure device, a resist material, and process conditions, but sufficient results have not been obtained. Note that the LWR and the LER are related, and the LER is improved by improving the LWR.

As a method for solving the above problems, there is disclosed a method for improving the LWR and LER by treating a resist pattern with an aqueous solution containing a specific ionic surfactant in a rinsing step after development process, to suppress defects (defects such as generation of residues and collapse of the pattern) caused by the development processing, and at the same time, dissolve the irregularities of the resist pattern (see Patent Literature 1).

### CITATION LIST

### Patent Literature

Patent Literature 1: JP 2007-213013 A

### SUMMARY OF INVENTION

### Technical Problem

An object of the present invention is to provide a resist underlayer film, a resist underlayer film-forming composition for EB or EUV lithography, a resist underlayer film for EB or EUV lithography, a semiconductor processing substrate, a method for producing a semiconductor element, a pattern forming method, and a method for improving the LWR of a resist pattern, which can improve the LWR of a resist pattern.

### Solution to Problem

As a result of intensive studies to solve the above problems, the present inventors have found that the above problems can be solved, and have completed the present invention having the following gist.

That is, the present invention includes the following.

[1] A resist underlayer film which is a baked product of a coating film of a resist underlayer film-forming composition,
the resist underlayer film-forming composition containing a polymer having at least one unit structure of a unit structure (A) having a polycyclic aromatic hydrocarbon structure, and a unit structure (B) having a maleimide structure, and
the resist underlayer film having a film thickness of less than 10 nm.

[2] The resist underlayer film according to [1], wherein the polycyclic aromatic hydrocarbon structure in the unit structure (A) includes at least one structure selected from the group consisting of naphthalene, anthracene, phenanthrene, carbazole, pyrene, triphenylene, chrysene, naphthacene, biphenylene, and fluorene.

[3] The resist underlayer film according to [1] or [2], wherein the unit structure (B) is represented by the following formula (4):

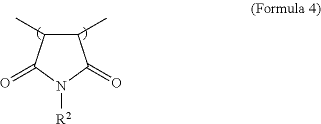

wherein R² represents a hydrogen atom, an alkyl group having 1 to 10 carbon atoms, which is optionally substituted with a hydroxy group, or an aryl group having 6 to 10 carbon atoms, which is optionally substituted with a halogen atom.

[4] The resist underlayer film according to any one of [1] to [3], wherein the polymer further has a unit structure (C) having a cross-linkable group.

[5] The resist underlayer film according to [4], wherein the cross-linkable group in the unit structure (C) includes at least one group selected from the group consisting of a hydroxy group, an epoxy group, a protected hydroxy group, and a protected carboxy group.

[6] The resist underlayer film according to any one of [1] to [5], wherein the resist underlayer film-forming composition further contains a crosslinking agent.

[7] The resist underlayer film according to any one of [1] to [6], wherein the resist underlayer film-forming composition further contains a curing catalyst.

[8] The resist underlayer film according to any one of [1] to [7], which is a resist underlayer film for EB or EUV lithography.

[9] A resist underlayer film-forming composition for EB or EUV lithography, including a polymer having at least one unit structure of a unit structure (A) having a polycyclic aromatic hydrocarbon structure and a unit structure (B) having a maleimide structure.

[10] The resist underlayer film-forming composition for EB or EUV lithography according to [9], wherein the polycyclic aromatic hydrocarbon structure in the unit structure (A) includes at least one structure selected from the group consisting of naphthalene, anthracene, phenanthrene, carbazole, pyrene, triphenylene, chrysene, naphthacene, biphenylene, and fluorene.

[11] The resist underlayer film-forming composition for EB or EUV lithography according to [9] or [10], wherein the unit structure (B) is represented by the following formula (4):

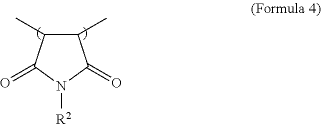

wherein R² represents a hydrogen atom, an alkyl group having 1 to 10 carbon atoms, which is optionally substituted with a hydroxy group, or an aryl group having 6 to 10 carbon atoms, which is optionally substituted with a halogen atom.

[12] The resist underlayer film-forming composition for EB or EUV lithography according to any one of [9] to [11], wherein the polymer further has a unit structure (C) having a cross-linkable group.

[13] The resist underlayer film-forming composition for EB or EUV lithography according to [12], wherein the cross-linkable group in the unit structure (C) includes at least one group selected from the group consisting of a hydroxy group, an epoxy group, a protected hydroxy group, and a protected carboxy group.

[14] The resist underlayer film-forming composition for EB or EUV lithography according to any one of [9] to [13], further including a crosslinking agent.

[15] The resist underlayer film-forming composition for EB or EUV lithography according to any one of [9] to [14], further including a curing catalyst.

[16] The resist underlayer film-forming composition for EB or EUV lithography according to any one of claims 9 to 15, which is used for forming the resist underlayer film according to any one of [1] to [8].

[17] A resist underlayer film for EB or EUV lithography, which is a baked product of a coating film of the resist underlayer film-forming composition for EB or EUV

[18] lithography according to any one of [9] to [16].

A semiconductor processing substrate including:
a semiconductor substrate; and
the resist underlayer film according to any one of [1] to [8] or the resist underlayer film for EB or EUV lithography according to.

[19] A method for producing a semiconductor element, including:
forming a resist underlayer film having a film thickness of less than 10 nm on a semiconductor substrate using the resist underlayer film-forming composition for EB or EUV lithography according to any one of [9] to [16]; and
forming a resist film on the resist underlayer film using a resist for EB or EUV lithography.

[20] A method for forming a pattern, including:
forming a resist underlayer film having a film thickness of less than 10 nm on a semiconductor substrate using the resist underlayer film-forming composition for EB or EUV lithography according to any one of [9] to;
forming a resist film on the resist underlayer film using a resist for EB or EUV lithography;
irradiating the resist film with EB or EUV, and then developing the resist film to obtain a resist pattern; and
etching the resist underlayer film using the resist pattern as a mask.

[21] A method for improving LWR of a resist pattern, including:
forming a resist underlayer film having a film thickness of less than 10 nm on a semiconductor substrate using the resist underlayer film-forming composition for EB or EUV lithography according to any one of [9] to [16];
forming a resist film on the resist underlayer film using a resist for EB or EUV lithography; and
irradiating the resist film with EB or EUV, and then developing the resist film to obtain a resist pattern.

### Advantageous Effects of Invention

According to the present invention it is possible to provide a resist underlayer film, a resist underlayer film-forming composition for EB or EUV lithography, a resist underlayer film for EB or EUV lithography, a semiconductor processing substrate, a method for producing a semiconductor element, a pattern forming method, and a method for improving the LWR of a resist pattern, which can improve the LWR of a resist pattern.

### DESCRIPTION OF EMBODIMENTS

The resist underlayer film of the present invention is a baked product of a coating film of a resist underlayer film-forming composition. Therefore, after the resist underlayer film-forming composition is described, the resist underlayer film of the present invention will be described.

### (Resist Underlayer Film-Forming Composition)

The resist underlayer film-forming composition of the present embodiment contains a polymer having at least one unit structure of a unit structure (A) having a polycyclic aromatic hydrocarbon structure and a unit structure (B) derived from a maleimide structure. The resist underlayer film-forming composition of the present embodiment can further contain a solvent, a crosslinking agent, and a curing catalyst in addition to the polymer. The resist underlayer film-forming composition of the present embodiment may contain other additives as long as the effect of the present invention is not impaired.

### <Polymer>

As described above, the polymer has at least one of the unit structure (A) having a polycyclic aromatic hydrocarbon structure and the unit structure (B) derived from a maleimide structure.

When the polymer has at least one of the unit structure (A) and the unit structure (B) derived from a maleimide structure, adhesion at the interface between the resist and the resist underlayer film in the formation of the resist pattern tends to be improved when the baked product of the coating film of the resist underlayer film-forming composition is used as a resist underlayer film. Therefore, it is estimated that deterioration of LWR in the formation of the resist pattern can be suppressed without causing stripping of the resist pattern. In particular, such a polymer exhibits a remarkable effect when EUV (wavelength: 13.5 nm) or EB (electron beam) is used.

In the present specification, the “polycyclic aromatic hydrocarbon structure” refers to an aromatic structure having a polycyclic aromatic hydrocarbon. In the present specification, the “unit structure derived from a maleimide structure” refers to a repeating unit in a polymer, and is a repeating unit obtained by reacting a carbon-carbon double bond of maleimide or a maleimide derivative. The maleimide derivative means a compound obtained by substituting the hydrogen atom of the NH group of maleimide.

### <<Unit Structure (A)>>

The unit structure (A) is a unit structure having a polycyclic aromatic hydrocarbon structure as described above.

In the present specification, the polycyclic aromatic hydrocarbon structure is an aromatic structure having a hydrocarbon composed of two or more aromatic rings exhibiting aromaticity, and includes a fused polycyclic aromatic hydrocarbon structure having a fused ring, and a hydrocarbon ring assembly structure having a plurality of aromatic rings directly bonded via a single bond.

In the present specification, the polycyclic aromatic hydrocarbon structure also includes a heterocyclic structure in which a part of a carbon of the aromatic ring is substituted with nitrogen.

The fused polycyclic aromatic hydrocarbon structure is not particularly limited, and examples thereof include a naphthalene structure, an anthracene structure, a phenanthrene structure, a pyrene structure, a triphenylene structure, a chrysene structure, a naphthacene structure, a biphenylene structure, and a fluorene structure.

The hydrocarbon ring assembly structure is not particularly limited, and examples thereof include a carbazole structure, a biphenyl structure, a terphenyl structure, a quaterphenyl structure, a binaphthalene structure, a phenylnaphthalene structure, a phenylfluorene structure, and a diphenylfluorene structure.

The polycyclic aromatic hydrocarbon structure is optionally substituted with a substituent. The substituent with which the polycyclic aromatic hydrocarbon structure is optionally substituted is not particularly limited, and examples thereof include an alkyl group, a hydroxy group, a carboxyl group, and a halogen group (for example, a fluorine group, a chlorine group, a bromine group, and an iodine group). Examples of the alkyl group include a methyl group, an ethyl group, an n-propyl group, an i-propyl group, an n-butyl group, an i-butyl group, an s-butyl group, a t-butyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, and a 1-ethyl-2-methyl-n-propyl group. Furthermore, a cyclic alkyl group can also be used as the alkyl group, and examples of a cyclic alkyl group having 1 to 10 carbon atoms include a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1, 2, 3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group.

From the viewpoint of suitably obtaining the effect of the present invention, the polycyclic aromatic hydrocarbon structure is preferably a naphthalene structure, an anthracene structure, a phenanthrene structure, a pyrene structure, a triphenylene structure, a chrysene structure, a naphthacene structure, a biphenylene structure, a fluorene structure, or a carbazole structure, more preferably a naphthalene structure, an anthracene structure, a phenanthrene structure, a pyrene structure, or a carbazole structure, and still more preferably a naphthalene structure or a carbazole structure.

The polycyclic aromatic hydrocarbon structure may be one type or two or more types, but is preferably one type or two types.

Specifically, the unit structure (A) is not particularly limited, but a unit structure represented by the following formula (1) can be suitably used.

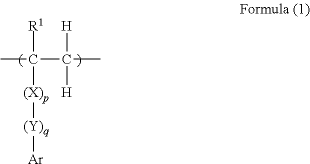

(In formula (1), R¹ represents a hydrogen atom or a methyl group, X represents an ester group or an amide group, Y represents an alkylene group having 1 to 6 carbon atoms, p and q each independently represent 0 or 1, and Ar represents a monovalent group obtained by removing a hydrogen atom from naphthalene, anthracene, phenanthrene, pyrene, triphenylene, chrysene, naphthacene, biphenylene, fluorene, or carbazole, which is optionally substituted.)

The unit structure (A) is not particularly limited, but a unit structure represented by the following formula (2) can be suitably used.

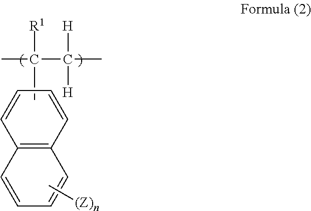

(In formula (2), R¹ represents a hydrogen atom or a methyl group, Z represents a halogen atom, a hydroxyl group, an alkyl group, an alkoxy group, a thiol group, a cyano group, a carboxyl group, an amino group, an amide group, an alkoxycarbonyl group, or a thioalkyl group, which is substituted with a naphthalene ring, n represents an integer of 0 to 7, and when n is 2 or more, two or more Zs may be the same or different.)

In Z, a fluorine atom, a chlorine atom, a bromine atom, or an iodine atom can be used as the halogen atom. The alkyl group is, for example, a linear or branched alkyl group having 1 to 6 carbon atoms, and these groups are optionally substituted with a halogen atom or the like. Examples of the alkyl group include a methyl group, an ethyl group, a propyl group, an isopropyl group, a butoxy group, a t-butoxy group, a n-hexyl group, and a chloromethyl group. The alkoxy group is, for example, an alkoxy group having 1 to 6 carbon atoms, and examples thereof include a methoxy group, an ethoxy group, and an isopropoxy group. The amide group is, for example, an amide group having 1 to 12 carbon atoms, and examples thereof include a formamide group, an acetamide group, a propionamide group, an isobutyramide group, a benzamide group, a naphthylamide group, and an acrylamide group. The alkoxycarbonyl group is, for example, an alkoxycarbonyl group having 1 to 12 carbon atoms, and examples thereof include a methoxycarbonyl group, an ethoxycarbonyl group, and a benzyloxycarbonyl group. The thioalkyl group is, for example, a thioalkyl group having 1 to 6 carbon atoms, and examples thereof include a methylthio group, an ethylthio group, a butylthio group, and a hexylthio group.

Specific examples of the unit structure (A) represented by formula (2) include the following.

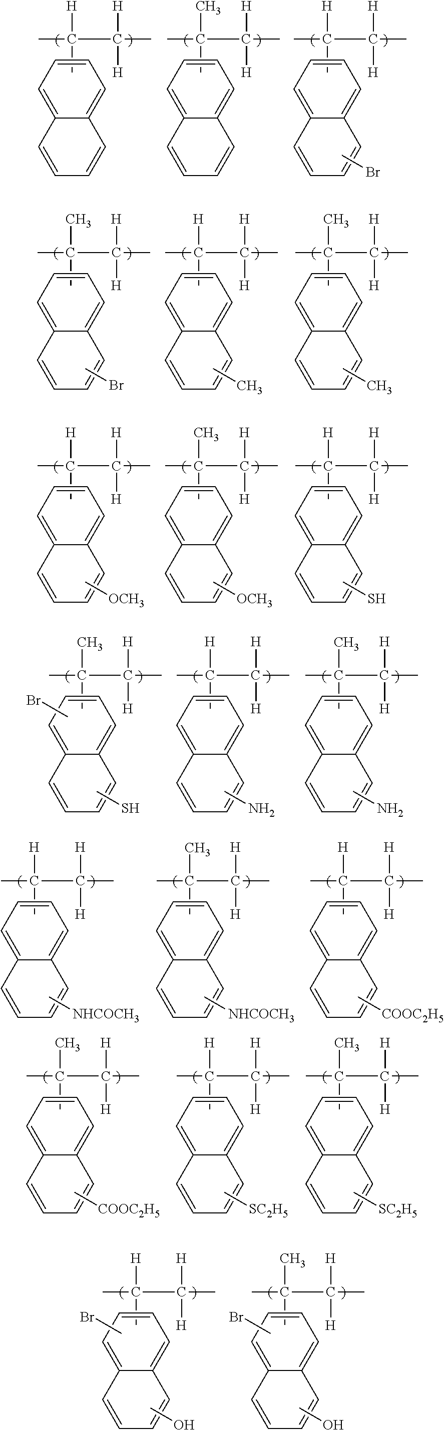

Furthermore, the unit structure (A) is not particularly limited, but a unit structure represented by the following formula (3) can be suitably used.

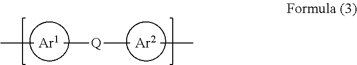

(In formula (3), Ar¹ and Ar² each independently represent an optionally substituted aromatic ring having 6 to 40 carbon atoms, at least one of Ar¹ and Ar² is naphthalene, anthracene, phenanthrene, or pyrene, and Q represents a single bond or a divalent linking group.)

Examples of the aromatic ring having 6 to 40 carbon atoms include benzene, naphthalene, anthracene, acenaphthene, fluorene, triphenylene, phenalene, phenanthrene, indene, indane, indacene, pyrene, chrysene, perylene, naphthacene, pentacene, coronene, heptacene, benzo[a]anthracene, dibenzophenanthrene, and dibenzo[a,j]anthracene.

Examples of the divalent linking group in Q include an ether group, an ester group, and an imino group, and an imino group is preferable.

The unit structure (A) may be one type or two or more types, but is preferably one type or two types.

When the polymer contains the unit structure (A), the molar ratio of the unit structure (A) is preferably 10 to 90 molo, more preferably 30 to 85 mol %, and still more preferably 40 to 80 mol % with respect to the total unit structure of the polymer from the viewpoint of suitably obtaining the effect of the present invention.

### <<Unit Structure (B)>>

The unit structure (B) is the unit structure derived from a maleimide structure described above.

The unit structure (B) is preferably a unit structure represented by the following formula (4).

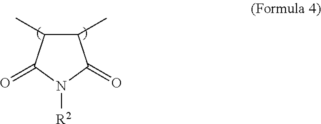

(In formula (4), R² represents a hydrogen atom, an alkyl group having 1 to 10 carbon atoms, which is optionally substituted with a hydroxy group, or an aryl group having 6 to 10 carbon atoms, which is optionally substituted with a halogen atom.)

The alkyl group having 1 to 10 carbon atoms may be linear, branched, or cyclic. Examples of the alkylene group having 1 to 10 carbon atoms include a methylene group, an ethylene group, an n-propylene group, an isopropylene group, a cyclopropylene group, an n-butylene group, an isobutylene group, an s-butylene group, a t-butylene group, a cyclobutylene group, a 1-methyl-cyclopropylene group, a 2-methyl-cyclopropylene group, an n-pentylene group, a 1-methyl-n-butylene group, a 2-methyl-n-butylene group, a 3-methyl-n-butylene group, a 1,1-dimethyl-n-propylene group, a 1,2-dimethyl-n-propylene group, a 2,2-dimethyl-n-propylene group, a 1-ethyl-n-propylene group, a cyclopentylene group, a 1-methyl-cyclobutylene group, a 2-methyl-cyclobutylene group, a 3-methyl-cyclobutylene group, a 1,2-dimethyl-cyclopropylene group, a 2,3-dimethyl-cyclopropylene group, a 1-ethyl-cyclopropylene group, a 2-ethyl-cyclopropylene group, an n-hexylene group, a 1-methyl-n-pentylene group, a 2-methyl-n-pentylene group, a 3-methyl-n-pentylene group, a 4-methyl-n-pentylene group, a 1,1-dimethyl-n-butylene group, a 1,2-dimethyl-n-butylene group, a 1,3-dimethyl-n-butylene group, a 2,2-dimethyl-n-butylene group, a 2,3-dimethyl-n-butylene group, a 3,3-dimethyl-n-butylene group, a 1-ethyl-n-butylene group, a 2-ethyl-n-butylene group, a 1,1,2-trimethyl-n-propylene group, a 1,2,2-trimethyl-n-propylene group, a 1-ethyl-1-methyl-n-propylene group, a 1-ethyl-2-methyl-n-propylene group, a cyclohexylene group, a 1-methyl-cyclopentylene group, a 2-methyl-cyclopentylene group, a 3-methyl-cyclopentylene group, a 1-ethyl-cyclobutylene group, a 2-ethyl-cyclobutylene group, a 3-ethyl-cyclobutylene group, a 1,2-dimethyl-cyclobutylene group, a 1,3-dimethyl-cyclobutylene group, a 2,2-dimethyl-cyclobutylene group, a 2,3-dimethyl-cyclobutylene group, a 2,4-dimethyl-cyclobutylene group, a 3,3-dimethyl-cyclobutylene group, a 1-n-propyl-cyclopropylene group, a 2-n-propyl-cyclopropylene group, a 1-isopropyl-cyclopropylene group, a 2-isopropyl-cyclopropylene group, a 1,2,2-trimethyl-cyclopropylene group, a 1, 2, 3-trimethyl-cyclopropylene group, a 2,2,3-trimethyl-cyclopropylene group, a 1-ethyl-2-methyl-cyclopropylene group, a 2-ethyl-1-methyl-cyclopropylene group, a 2-ethyl-2-methyl-cyclopropylene group, a 2-ethyl-3-methyl-cyclopropylene group, an n-heptylene group, an n-octylene group, an n-nonylene group, and an n-decanylene group.

Any optional hydrogen atom of the alkyl group having 1 to 10 carbon atoms is optionally substituted with a hydroxy group.

The halogen atom is as described above. Examples of the aryl group having 6 to 10 carbon atoms include a phenyl group, a benzyl group, and a naphthyl group.

Specific examples of the unit structure (B) represented by formula (4) include the following unit structures.

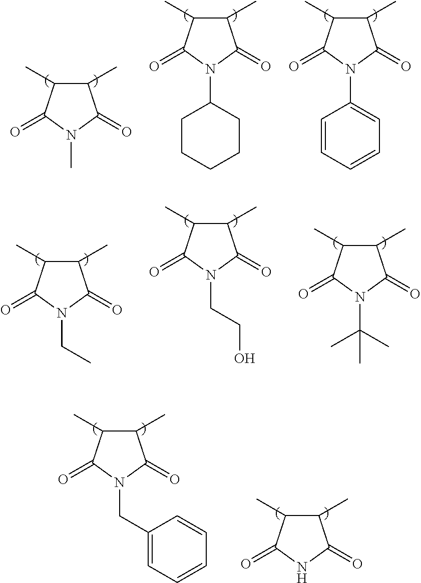

The unit structure (B) may be one type or two or more types, but is preferably one type or two types.

When the polymer contains the unit structure (B), the molar ratio of the unit structure (B) is preferably 10 to 90 mol %, more preferably 10 to 75 mol %, and still more preferably 10 to 50 mol % with respect to the total unit structure of the polymer from the viewpoint of suitably obtaining the effect of the present invention.

When the polymer contains the unit structure (A) and the unit structure (B), the total molar ratio of the unit structure (A) and the unit structure (B) is preferably 20 mol % or more, more preferably 40 mol % or more, and still more preferably 50 mol % or more with respect to the total unit structure of the polymer from the viewpoint of suitably obtaining the effect of the present invention.

### <<Unit Structure (C)>>

The polymer of the present embodiment may optionally further contain a unit structure (C) having a cross-linkable group in addition to the unit structure (A) and/or the unit structure (B).

The cross-linkable group can cause a crosslinking reaction with a crosslinking agent component which is optionally introduced into the resist underlayer film-forming composition of the present invention during heating and baking. The resist underlayer film formed by such a crosslinking reaction has an effect of preventing intermixing with a resist film to be applied as an upper layer.

The cross-linkable group is not particularly limited as long as it is a group that generates a chemical bond between molecules, and can be, for example, a hydroxy group, an epoxy group, a protected hydroxy group, or a protected carboxyl group. Any number of cross-linkable groups may be present in one molecule.

Examples of the hydroxy group include hydroxy groups derived from hydroxyalkyl (meth)acrylate, vinyl alcohol, and the like, and phenolic hydroxy groups derived from hydroxystyrene and the like. Examples of the alkyl group include the above-described alkyl groups, and examples thereof include a methyl group, an ethyl group, a propyl group, an isopropyl group, and a butyl group. In the present specification, (meth)acrylate means both methacrylate and acrylate.

Examples of the epoxy group include epoxy groups derived from epoxy (meth)acrylate, and glycidyl (meth)acrylate.

Examples of the protected hydroxy group include a group in which the hydroxy group of hydroxystyrene is protected with a tert-butoxy group. Other examples of the protected hydroxy group include a hydroxy group protected by reacting a phenolic hydroxy group such as hydroxystyrene with a vinyl ether compound, and a hydroxy group protected by reacting an alcoholic hydroxy group such as hydroxyethyl methacrylate with a vinyl ether compound. Examples of the vinyl ether compound include aliphatic vinyl ether compounds having an alkyl chain having 1 to 10 carbon atoms and a vinyl ether group, such as methyl vinyl ether, ethyl vinyl ether, isopropyl vinyl ether, normal butyl vinyl ether, 2-ethylhexyl vinyl ether, tert-butyl vinyl ether, and cyclohexyl vinyl ether, and cyclic vinyl ether compounds such as 2,3-dihydrofuran, 4-methyl-2,3-dihydrofuran, and 2,3-dihydro-4H-pyran.

Examples of the protected carboxyl group include a carboxyl group protected by reacting a carboxyl group of (meth)acrylic acid or vinylbenzoic acid with a vinyl ether compound. Examples of the vinyl ether compound used here include the vinyl ether compounds described above.

Examples of the cross-linkable group include an amino group, an isocyanate group, a protected amino group, and a protected isocyanate group. The amino group is required to have at least one active hydrogen, but an amino group obtained by substituting one active hydrogen of the amino group with an alkyl group or the like can also be used. As the alkyl group, the above-described alkyl groups can be used.

The protected amino group is an amino group obtained by protecting at least one hydrogen atom of an amino group with an alkoxycarbonyl group such as a t-butoxycarbonyl group or a 9-fluorenylmethoxycarbonyl group.

The protected isocyanate group is a protected group obtained by reacting an isocyanate group with a protecting agent. The protecting agent is an active hydrogen-containing compound capable of reacting with an isocyanate, and examples thereof include an alcohol, a phenol, a polycyclic phenol, an amide, an imide, an imine, a thiol, an oxime, a lactam, an active hydrogen-containing heterocyclic ring, and an active methylene-containing compound.

Examples of the alcohol as the protecting agent include alcohols having 1 to 40 carbon atoms, and examples thereof include methanol, ethanol, propanol, isopropanol, butanol, pentanol, hexanol, octanol, ethylene chlorohydrin, 1,3-dichloro-2-propanol, t-butanol, t-pentanol, 2-ethylhexanol, cyclohexanol, lauryl alcohol, ethylene glycol, butylene glycol, trimethylolpropane, glycerin, ethylene glycol monomethyl ether, ethylene glycol monoethyl ether, ethylene glycol monobutyl ether, diethylene glycol monomethyl ether, propylene glycol monomethyl ether, propylene glycol monoethyl ether, and benzyl alcohol.

Examples of the phenol as the protecting agent include phenols having 6 to 20 carbon atoms, and examples thereof include phenol, chlorophenol, and nitrophenol.

Examples of the phenol derivative as the protecting agent include phenol derivatives having 6 to 20 carbon atoms, and examples thereof include para-t-butylphenol, cresol, xylenol, and resorcinol.

Examples of the polycyclic phenol as the protecting agent include polycyclic phenols having 10 to 20 carbon atoms, which are aromatic fused rings having a phenolic hydroxy group, and examples thereof include hydroxynaphthalene and hydroxyanthracene.

Examples of the amide as the protecting agent include amides having 1 to 20 carbon atoms, and examples thereof include acetanilide, hexanamide, octanediamide, succinamide, benzenesulfonamide, and ethanediamide.

Examples of the imide as the protecting agent include imides having 6 to 20 carbon atoms, and examples thereof include cyclohexanedicarboximide, cyclohexaenedicarboximide, benzenedicarboximide, cyclobutanedicarboximide, and carbodiimide.

Examples of the imine as the protecting agent include imines having 1 to 20 carbon atoms, and examples thereof include hexane-1-imine, 2-propaneimine, and ethane-1,2-imine.

Examples of the thiol as the protecting agent include thiols having 1 to 20 carbon atoms, and examples thereof include ethanethiol, butanethiol, thiophenol, and 2,3-butanedithiol.

The oxime as the protecting agent is, for example, an oxime having 1 to 20 carbon atoms, and examples thereof include acetoxime, methyl ethyl ketoxime, cyclohexanone oxime, dimethyl ketoxime, methyl isobutyl ketoxime, methyl amyl ketoxime, formamide oxime, acetaldoxime, diacetyl monoxime, benzophenone oxime, and cyclohexaneoxime.

The lactam as the protecting agent is, for example, a lactam having 4 to 20 carbon atoms, and examples thereof include ε-caprolactam, δ-valerolactam, γ-butyrolactam, β-propyllactam, γ-pyrrolidone, and lauryllactam.

The active hydrogen-containing heterocyclic compound as the protecting agent is, for example, an active hydrogen-containing heterocyclic compound having 3 to 30 carbon atoms, and examples thereof include pyrrole, imidazole, pyrazole, piperidine, piperazine, morpholine, pyridine, indole, indazole, purine, and carbazole.

The active methylene-containing compound as the protecting agent is, for example, an active methylene-containing compound having 3 to 20 carbon atoms, and examples thereof include dimethyl malonate, diethyl malonate, methyl acetoacetate, ethyl acetoacetate, and acetylacetone.

The cross-linkable group is not particularly limited, but a hydroxy group can be preferably used. As the unit structure (C) having these cross-linkable groups, a unit structure derived from the hydroxyalkyl (meth)acrylate is preferable, and in particular, a unit structure derived from hydroxyethyl (meth)acrylate is more preferable.

The “unit structure derived from hydroxyalkyl (meth)acrylate” refers to a repeating unit in a polymer obtained by reacting a carbon-carbon double bond of hydroxyalkyl (meth)acrylate.

When the polymer contains the unit structure (C), the molar ratio of the unit structure (C) is preferably 5 to 90 mol %, more preferably 10 to 80 mol %, and still more preferably 15 to 75 mol % with respect to the total unit structure of the polymer from the viewpoint of suitably obtaining the effect of the present invention.

### <<Characteristics of Polymer>>

The distribution of the unit structures represented by the unit structures (A), (B) and (C) in the polymer is not particularly limited. The polymer may be a homopolymer of the unit structure (A) or a homopolymer of the unit structure (B), but preferably has at least the unit structure (A). When the polymer is a copolymer of the unit structure (A) and the unit structure (B), the unit structure (A) and the unit structure (B) may be alternately copolymerized or randomly copolymerized. When the unit structure (C) coexists, each unit structure in the polymer may constitute a block or may be randomly bonded.

The molecular weight of the polymer is not particularly limited, but the weight average molecular weight measured by gel permeation chromatography (hereinafter, may be abbreviated as GPC) is preferably 1,500 to 100,000 and more preferably 2,000 to 50,000.

### <<Method for Producing Polymer>>

The method for producing the polymer is not particularly limited, but for example, the polymer of the present embodiment can be obtained by reacting a carbon-carbon double bond of the monomer of the unit structure (A), a carbon-carbon double bond of the monomer of the unit structure (B), and a carbon-carbon double bond of the monomer of the optional unit structure (C).

As a polymer polymerization method, a known polymerization method such as radical polymerization, anionic polymerization, or cationic polymerization can be used. Various known techniques such as solution polymerization, suspension polymerization, emulsion polymerization, and bulk polymerization can be used.

The polymerization initiator used in the polymerization is not particularly limited, and examples thereof include 2,2′-azobis(isobutyronitrile), 2,2′-azobis(2-methylbutyronitrile), 2,2′-azobis(2,4-dimethylvaleronitrile), 4,4′-azobis(4-cyanovaleric acid), 2,2′-azobis(2,4-dimethylvaleronitrile), 2,2′-azobis(4-methoxy-2,4-dimethylvaleronitrile), 2,2′-azobis(isobutyronitrile), 1,1′-azobis(cyclohexane-1-carbonitrile), 1-[(1-cyano-1-methylethyl)azo]formamide, 2,2′-azobis[2-(2-imidazolin-2-yl)propane]dihydrochloride, 2,2′-azobis[2-(2-imidazolin-2-yl)propane], and 2,2′-azobis(2-methylpropionamidine) dihydrochloride.

The solvent used in the polymerization is not particularly limited, and examples of the solvent that can be used include dioxane, ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol propyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, and butyl lactate. These may be used alone or in combination.

The reaction temperature is not particularly limited, and is, for example, 20° C. to 160° C.

The reaction time is not particularly limited, and is, for example, 1 hour to 72 hours.

A solution containing the obtained polymer can also be used as it is for the preparation of the resist underlayer film-forming composition. The polymer can also be used by being isolated by precipitation in a poor solvent such as methanol, ethanol, isopropanol, or water, or a mixed solvent thereof and recovered.

The content of the polymer in the resist underlayer film-forming composition is not particularly limited, but is preferably 0.1 mass % to 50 mass %, and more preferably 0.1 mass % to 10 mass % with respect to the entire resist underlayer film-forming composition from the viewpoint of solubility.

### <Crosslinking Agent>

The crosslinking agent contained as an optional component in the resist underlayer film-forming composition may be a nitrogen-containing compound having, in one molecule, 2 to 6 substituents represented by the following formula (1d) which are bonded to a nitrogen atom as described in WO 2017/187969 A.

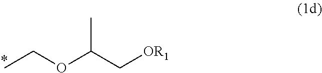

(In formula (1d), R₁ represents a methyl group or an ethyl group, and * represents a bond bonded to a nitrogen atom.)

The nitrogen-containing compound having 2 to 6 substituents represented by the above formula (1d) in one molecule may be a glycoluril derivative represented by the following formula (1E).

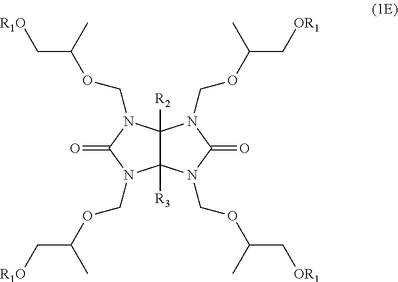

(In formula (1E), four R₁s each independently represent a methyl group or an ethyl group, and R² and R³ each independently represent a hydrogen atom, an alkyl group having 1 to 4 carbon atoms, or a phenyl group.)

Examples of the glycoluril derivative represented by the above formula (1E) include compounds represented by the following formulas (1E-1) to (1E-6).

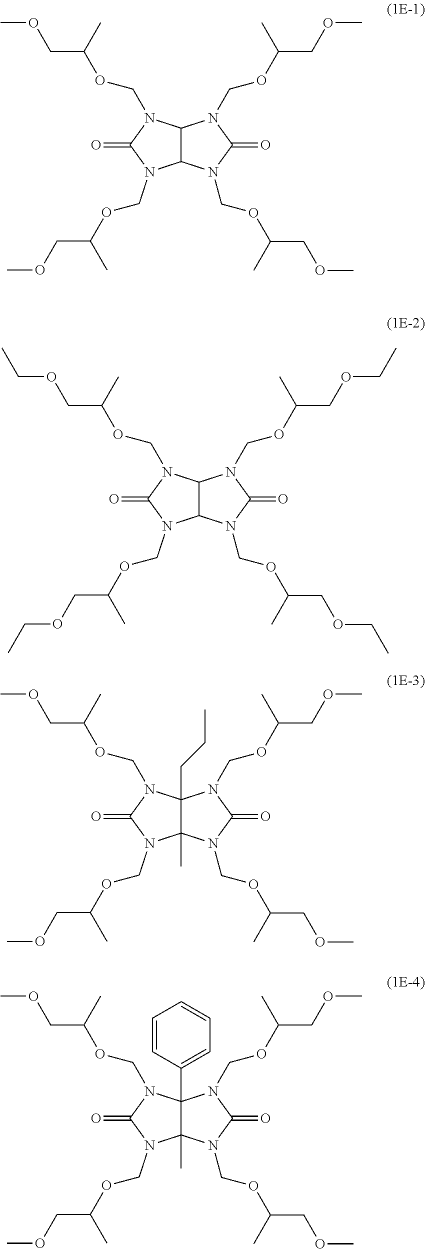

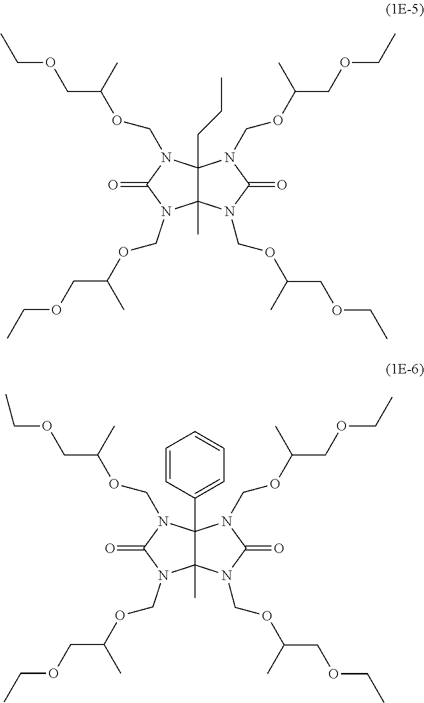

The nitrogen-containing compound having 2 to 6 substituents represented by the above formula (1d) in one molecule is obtained by reacting a nitrogen-containing compound having, in one molecule, 2 to 6 substituents represented by the following formula (2d) which are bonded to a nitrogen atom with at least one compound represented by the following formula (3d).

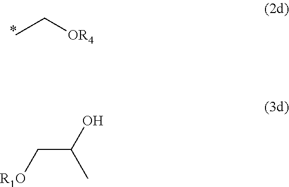

(In formulas (2d) and (3d), R₁ represents a methyl group or an ethyl group, R₄ represents an alkyl group having 1 to 4 carbon atoms, and * represents a bond bonded to a nitrogen atom.)

The glycoluril derivative represented by the above formula (1E) is obtained by reacting a glycoluril derivative represented by the following formula (2E) with at least one compound represented by the above formula (3d).

The nitrogen-containing compound having 2 to 6 substituents represented by the above formula (2d) in one molecule is, for example, a glycoluril derivative represented by the following formula (2E).

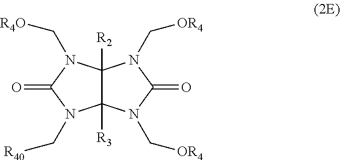

(In formula (2E), R₂ and R₃ each independently represent a hydrogen atom, an alkyl group having 1 to 4 carbon atoms, or a phenyl group, and R₄ each independently represents an alkyl group having 1 to 4 carbon atoms.)

Examples of the glycoluril derivative represented by the above formula (2E) include compounds represented by the following formulas (2E-1) to (2E-4). Furthermore, examples of the compound represented by the above formula (3d) include compounds represented by the following formulas (3d-1) and (3d-2).

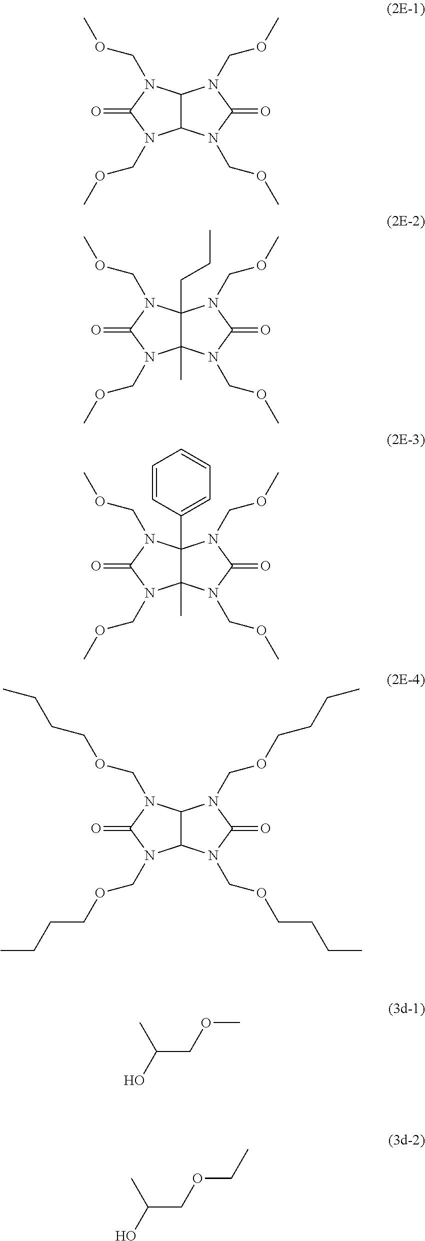

For the details related to the nitrogen-containing compound having, in one molecule, 2 to 6 substituents represented by formula (1d) which are bonded to a nitrogen atom, the entire disclosure of WO2017/187969 is incorporated in the present application.

The crosslinking agent may be a compound represented by the following formula (21).

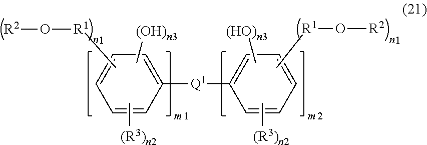

(In formula (21), R¹ each independently represents an alkylene group having 1 to 6 carbon atoms, R² each independently represents a hydrogen atom, an alkyl group having 1 to 6 carbon atoms, or an alkoxyalkyl group having 2 to 10 carbon atoms in total, R³ each independently represents an alkyl group having 1 to 6 carbon atoms, m1 and m2 each independently represent an integer of 1 to 2, when m1 and m2 are 1, Q¹ represents a single bond, an oxygen atom, or a divalent organic group having 1 to 20 carbon atoms, and otherwise, Q¹ represents a (m1+m2)-valent organic group having 1 to 20 carbon atoms.)

Examples of the (m1+m2)-valent organic group having 1 to 20 carbon atoms in Q include groups represented by any of the following formulas (21-1) to (21-5).

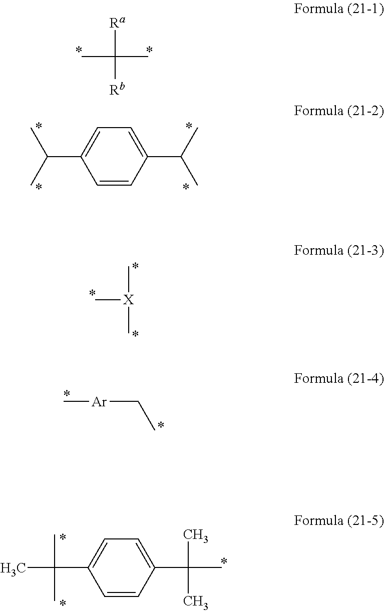

(In formula (21-1), Ra and Rb each independently represent a hydrogen atom, an alkyl group having 1 to 4 carbon atoms, or a —CF₃ group.

In formula (21-3), X represents a trivalent group having 1 to 30 carbon atoms.

In formula (21-4), Ar represents a divalent aromatic hydrocarbon group, and
* represents a bond.)

Ar represents, for example, a divalent residue of a compound selected from benzene, biphenyl, naphthalene, and anthracene.

The group represented by formula (21-1) is a divalent group.

The group represented by formula (21-2) is a tetravalent group.

The group represented by formula (21-3) is a trivalent group.

The group represented by formula (21-4) is a divalent group.

The group represented by formula (21-5) is a trivalent group.

When the crosslinking agent is used, the content of the crosslinking agent is, for example, 1 mass % to 50 mass, preferably 5 mass % to 30 mass % with respect to the polymer having at least one unit structure of the unit structure (A) and the unit structure (B).

### <<Curing Catalyst>>

As the curing catalyst contained as an optional component in the resist underlayer film-forming composition, both a thermal acid generator and a photoacid generator can be used, but it is preferable to use a thermal acid generator.

Examples of the thermal acid generator include sulfonic acid compounds and carboxylic acid compounds such as p-toluenesulfonic acid, trifluoromethanesulfonic acid, pyridinium-p-toluenesulfonate (pyridinium-p-toluenesulfonic acid), pyridinium phenol sulfonic acid, pyridinium-p-hydroxybenzenesulfonic acid (p-phenolsulfonic acid pyridinium salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generator include onium salt compounds, sulfonimide compounds, and disulfonyldiazomethane compounds.

Examples of the onium salt compound include iodonium salt compounds such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

Only one type of curing catalyst can be used, or two or more types thereof can be used in combination.

When a curing catalyst is used, the content of the curing catalyst is, for example, 0.1 mass % to 50 mass, preferably 1 mass % to 30 mass % with respect to the crosslinking agent.

### <<Other Components>>

In the resist underlayer film-forming composition, a surfactant can be further added in order to prevent generation of pinholes, striations, and the like, and further improve the coatability for surface unevenness.

Examples of the surfactant include nonionic surfactants including polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl allyl ethers such as polyoxyethylene octylphenol ether and polyoxyethylene nonylphenol ether, polyoxyethylene/polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants such as EFTOP EF301, EF303, and EF352 (trade name, manufactured by TOOKEMU PURODAKUTSU KK), MEGAFACE F171, F173, and R-30 (trade name, manufactured by DIC Corporation), Fluorad FC430 and FC431 (trade name, manufactured by Sumitomo 3M Limited), AsahiGuard AG710, and Surflon S-382, SC101, SC102, SC103, SC104, SC105, and SC106 (trade name, manufactured by AGC Inc.); and organosiloxane polymer KP341 (manufactured by Shin-Etsu Chemical Co., Ltd.).

The blending amount of these surfactants is not particularly limited, but is usually 2.0 mass % or less, and preferably 1.0 mass % or less with respect to the resist underlayer film-forming composition.

These surfactants may be added alone, or may be added in combination of two or more types thereof.

### <Solvent>

As the solvent, an organic solvent generally used for a chemical solution for a semiconductor lithography process is preferable. Specific examples of the solvent include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxy cyclopentane, anisole, γ-butyrolactone, N-methylpyrrolidone, N,N-dimethylformamide, and N,N-dimethylacetamide. These solvents can be used alone or in combination of two or more types thereof.

Among these solvents, propylene glycol monomethyl ether, propylene glycol monomethyl ether acetate, ethyl lactate, butyl lactate, and cyclohexanone are preferable. In particular, propylene glycol monomethyl ether and propylene glycol monomethyl ether acetate are preferable.

The resist underlayer film-forming composition is preferably used as a resist underlayer film-forming composition for EB or EUV lithography. The resist underlayer film-forming composition for EB or EUV lithography is preferably used for forming a resist underlayer film for EB or EUV lithography having a film thickness of less than 10 nm.

### (Resist Underlayer Film)

The resist underlayer film of the present invention is a baked product of the coating film of the resist underlayer film-forming composition described above.

The film thickness of the resist underlayer film of the present invention is less than 10 nm. Usually, when the film thickness of the resist underlayer film is reduced, it is difficult to obtain a film having a flat surface. When the surface is not flat, the variation in the film thickness of the resist layer to be formed on the underlayer film increases, resulting in an increase in the LWR.

When the resist underlayer film of the present invention contains the above-described polymer, the resist underlayer film tends to be excellent in adhesion to a substrate and film formability. Therefore, it is estimated that even when the film thickness of the resist underlayer film is less than 10 nm, a film having a flat surface can be formed, and thus the LWR of the resist pattern can be improved. In particular, the resist underlayer film of the present invention exhibits a remarkable effect when EUV or EB is used.

Note that, when a resist underlayer film having a film thickness of 20 nm or more is used at the time of using EUV or EB, the film thickness of the resist film is thin in the dry etching step after formation of the resist pattern. Therefore, the resist pattern is damaged in the process of etching the underlayer film to cause shape defects such as a decrease in the resist film thickness or a top rounding shape, thus making it difficult to form a pattern having a target line width when the substrate is actually processed.

The resist underlayer film of the present invention can be produced by applying a resist underlayer film-forming composition on a semiconductor substrate and baking the composition.

Examples of the semiconductor substrate to which the resist underlayer film-forming composition of the present invention is applied include silicon wafers, germanium wafers, and wafers of semiconductor compounds such as gallium arsenide, indium phosphide, gallium nitride, indium nitride, and aluminum nitride.

When a semiconductor substrate having an inorganic film formed on a surface thereof is used, the inorganic film is formed by, for example, an atomic layer deposition (ALD) method, a chemical vapor deposition (CVD) method, a reactive sputtering method, an ion plating method, a vacuum deposition method, or a spin coating method (spin on glass: SOG). Examples of the inorganic film include a polysilicon film, a silicon oxide film, a silicon nitride film, a boro-phospho silicate glass (BPSG) film, a titanium nitride film, a titanium oxynitride film, a tungsten film, a gallium nitride film, and a gallium arsenide film.

The resist underlayer film-forming composition of the present invention is applied onto such a semiconductor substrate by an appropriate application method such as a spinner or a coater. Thereafter, the applied composition is baked with heating means such as a hot plate to thereby form a resist underlayer film. The baking conditions are appropriately selected from a baking temperature of 100° C. to 400° C. and a baking time of 0.3 minutes to 60 minutes. The baking temperature is preferably 120° C. to 350° C., and the baking time is 0.5 minutes to 30 minutes, more preferably 150° C. to 300° C., and the baking time is 0.8 minutes to 10 minutes.

The film thickness of the resist underlayer film is less than 10 nm, preferably 9 nm or less, more preferably 8 nm or less, and still more preferably 7 nm or less. The film thickness of the resist underlayer film may be 1 nm or more, 2 nm or more, or 3 nm or more.

The method of measuring the film thickness of the resist underlayer film in the present specification is as follows.
Measuring apparatus name: ellipsometric film thickness measurement system RE-3100 (SCREEN Semiconductor Solutions Co., Ltd.)
Single wavelength ellipsometer (SWE) mode
Arithmetic average of eight points (for example, eight points are measured at intervals of 1 cm in the wafer X direction)

The resist underlayer film is preferably used as a resist underlayer film for EB or EUV lithography.

### (Semiconductor Processing Substrate)

The semiconductor processing substrate according to the present invention includes: a semiconductor substrate; and a resist underlayer film or a resist underlayer film for EB or EUV lithography according to the present invention.

Examples of the semiconductor substrate include the above-described semiconductor substrates.

The resist underlayer film or the resist underlayer film for EB or EUV lithography is disposed on, for example, the semiconductor substrate.

### (Method for Producing Semiconductor Element, Pattern Forming Method, and Method for Improving LWR of Resist Pattern)

The method for producing a semiconductor element of the present invention includes at least the following steps:
forming a resist underlayer film having a film thickness of less than 10 nm on a semiconductor substrate using the resist underlayer film-forming composition for EB or EUV lithography of the present invention; and
forming a resist film on the resist underlayer film using a resist for EB or EUV lithography.

The pattern forming method of the present invention includes at least the following steps:
forming a resist underlayer film having a film thickness of less than 10 nm on a semiconductor substrate using the resist underlayer film-forming composition for EB or EUV lithography of the present invention;
forming a resist film on the resist underlayer film using a resist for EB or EUV lithography;
irradiating the resist film with EB or EUV, and then developing the resist film to obtain a resist pattern; and
etching the resist underlayer film using the resist pattern as a mask.

The method for improving the LWR of the resist pattern of the present invention includes at least the following steps:
forming a resist underlayer film having a film thickness of less than 10 nm on a semiconductor substrate using the resist underlayer film-forming composition for EB or EUV lithography of the present invention;
forming a resist film on the resist underlayer film using a resist for EB or EUV lithography; and
irradiating the resist film with EB or EUV, and then developing the resist film to obtain a resist pattern.

In the method for improving the LWR of the resist pattern, the unevenness of the resist pattern width (line width roughness: (LWR)) in EB or EUV lithography can be improved by using a resist underlayer film obtained from the resist underlayer film-forming composition for EB or EUV lithography of the present invention under a resist film.

Usually, the resist film is formed on the resist underlayer film.

The film thickness of the resist film is not particularly limited, but is preferably 200 nm or less, more preferably 150 nm or less, still more preferably 100 nm or less, and particularly preferably 80 nm or less. The film thickness of the resist film is preferably 10 nm or more, more preferably 20 nm or more, and still more preferably 30 nm or more.

The resist to be formed on the resist underlayer film by coating and baking by a known method is not particularly limited as long as it responds to EB or EUV used for irradiation. Both a negative photoresist and a positive photoresist can be used.

In the present specification, a resist responding to EB is also referred to as a photoresist.

Examples of the photoresist include a positive photoresist composed of a novolak resin and 1,2-naphthoquinone diazide sulfonic acid ester; a chemically amplified photoresist composed of a binder having a group which is decomposed by an acid to increase the alkali dissolution rate and a photoacid generator; a chemically amplified photoresist composed of a low-molecular weight compound which is decomposed by an acid to increase the alkali dissolution rate of the photoresist, an alkali-soluble binder, and a photoacid generator; a chemically amplified photoresist composed of a binder having a group which is decomposed by an acid to increase the alkali dissolution rate, a low-molecular weight compound which is decomposed by an acid to increase the alkali dissolution rate of the photoresist, and a photoacid generator; and a resist containing a metal element. Examples of such photoresists include trade name V146G manufactured by JSR Corporation, trade name APEX-E manufactured by Shipley, trade name PAR710 manufactured by Sumitomo Chemical Co., Ltd., and trade name AR2772 and SEPR430 manufactured by Shin-Etsu Chemical Co., Ltd. Other examples of the photoresist include fluorine-containing atomic polymer-based photoresists as described in Proc. SPIE, Vol. 3999, 330-334 (2000), Proc. SPIE, Vol. 3999, 357-364 (2000), and Proc. SPIE, Vol. 3999, 365-374 (2000).

In addition, so-called resist compositions and metal-containing resist compositions, such as resist compositions, radiation-sensitive resin compositions, and high-resolution patterning compositions based on organometallic solutions described in the following patent literatures can be used. Examples thereof include, but are not limited thereto, resist compositions and metal-containing resist compositions described in WO2019/188595, WO2019/187881, WO2019/187803, WO2019/167737, WO2019/167725, WO2019/187445, WO2019/167419, WO2019/123842, WO2019/054282, WO2019/058945, WO2019/058890, WO2019/039290, WO2019/044259, WO2019/044231, WO2019/026549, WO2018/193954, WO2019/172054, WO2019/021975, WO2018/230334, WO2018/194123, JP 2018-180525, WO2018/190088, JP 2018-070596, JP 2018-028090, JP 2016-153409, JP 2016-130240, JP 2016-108325, JP 2016-047920, JP 2016-035570, JP 2016-035567, JP 2016-035565, JP 2019-101417, JP 2019-117373, JP 2019-052294, JP 2019-008280, JP 2019-008279, JP 2019-003176, JP 2019-003175, JP 2018-197853, JP 2019-191298, JP 2019-061217, JP 2018-045152, JP 2018-022039, JP 2016-090441, JP 2015-10878, JP 2012-168279, JP 2012-022261, JP 2012-022258, JP 2011-043749, JP 2010-181857, JP 2010-128369, WO2018/031896, JP 2019-113855, WO2017/156388, WO2017/066319, JP 2018-41099, WO2016/065120, WO2015/026482, JP 2016-29498, and JP 2011-253185.

Examples of the resist composition include the following compositions.

An actinic ray-sensitive or radiation-sensitive resin composition containing: a resin A having a repeating unit having an acid-decomposable group in which a polar group is protected by a protecting group that is desorbed by an action of an acid; and a compound represented by the following general formula (21).

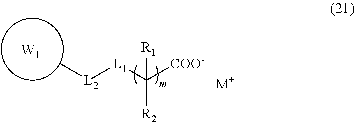

In general formula (21), m represents an integer of 1 to 6.

R₁ and R₂ each independently represent a fluorine atom or a perfluoroalkyl group.

L₁ represents —O—, —S—, —COO—, —SO₂—, or —SO₃—.

L₂ represents an alkylene group optionally having a substituent or a single bond.

W₁ represents a cyclic organic group optionally having a substituent.

M⁺ represents a cation.

A metal-containing film-forming composition for extreme ultraviolet or electron beam lithography, containing: a compound having a metal-oxygen covalent bond; and a solvent, wherein metal elements constituting the compound belong to the third to seventh periods of Groups 3 to 15 of the periodic table.

A radiation-sensitive resin composition containing: a polymer having a first structural unit represented by the following formula (31), and a second structural unit represented by the following formula (32) and having an acid-dissociable group; and an acid generator.

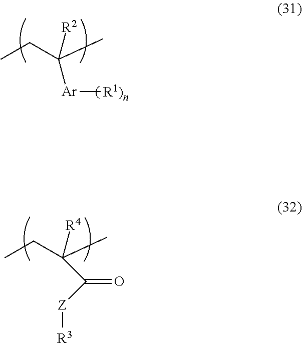

(In formula (31), Ar is a group obtained by removing (n+1) hydrogen atoms from an arene having 6 to 20 carbon atoms, R¹ is a hydroxy group, a sulfanyl group, or a monovalent organic group having 1 to 20 carbon atoms, n is an integer of 0 to 11, when n is 2 or more, a plurality of R¹s are the same or different, and R¹ is a hydrogen atom, a fluorine atom, a methyl group, or a trifluoromethyl group. In formula (32), R³ is a monovalent group having 1 to 20 carbon atoms, which includes the above-described acid-dissociable group, Z is a single bond, an oxygen atom, or a sulfur atom, and R⁴ is a hydrogen atom, a fluorine atom, a methyl group, or a trifluoromethyl group.)

A resist composition containing: a resin (A1) having a structural unit having a cyclic carbonic acid ester structure, a structural unit represented by the following formula, and a structural unit having an acid-unstable group; and an acid generator.

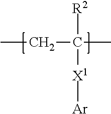

[In the formula,

R₂ represents an alkyl group having 1 to 6 carbon atoms, which optionally has a halogen atom, a hydrogen atom, or a halogen atom, X′ represents a single bond, —CO—O—* or —CO—NR⁴—*, * represents a bond with —Ar, R⁴ represents a hydrogen atom or an alkyl group having 1 to 4 carbon atoms, and Ar represents an aromatic hydrocarbon group having 6 to 20 carbon atoms, which optionally has one or more groups selected from the group consisting of a hydroxy group and a carboxyl group.]

Examples of the resist film include the following.

A resist film containing a base resin containing a repeating unit represented by the following formula (a1) and/or a repeating unit represented by the following formula (a2), and a repeating unit that generates an acid bonded to a polymer main chain by exposure.

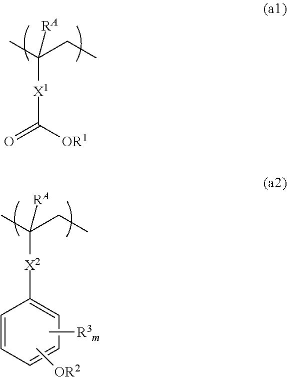

(In formulas (a1) and (a2), R^{A} is each independently a hydrogen atom or a methyl group, R¹ and R² are each independently a tertiary alkyl group having 4 to 6 carbon atoms, R³ is each independently a fluorine atom or a methyl group, m is an integer of 0 to 4, X¹ is a single bond, a phenylene group or a naphthylene group, or a linking group having 1 to 12 carbon atoms, which includes at least one selected from an ester bond, a lactone ring, a phenylene group, and a naphthylene group, and X² is a single bond, an ester bond, or an amide bond.)

Examples of the resist material include the following.

A resist material containing a polymer having a repeating unit represented by the following formula (b1) or formula (b2).

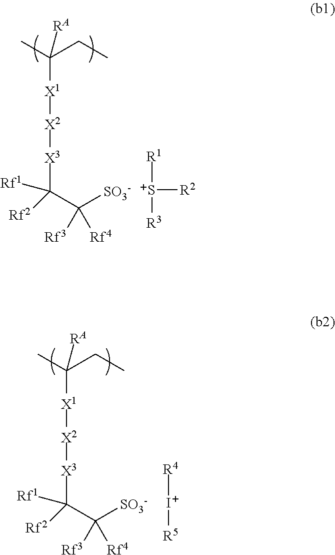

(In formulas (b1) and (b2), R^{A} is a hydrogen atom or a methyl group; X¹ is a single bond or an ester group; X² is a linear, branched or cyclic alkylene group having 1 to 12 carbon atoms or an arylene group having 6 to 10 carbon atoms, a part of the methylene group constituting the alkylene group is optionally substituted with an ether group, an ester group or a lactone ring-containing group, and at least one hydrogen atom contained in X² is substituted with a bromine atom; X³ is a single bond, an ether group, an ester group or a linear, branched or cyclic alkylene group having 1 to 12 carbon atoms, and a part of the methylene group constituting the alkylene group is optionally substituted with an ether group or an ester group; Rf¹ to Rf⁴ are each independently a hydrogen atom, a fluorine atom, or a trifluoromethyl group, at least one of which is a fluorine atom or a trifluoromethyl group, and Rf¹ and Rf² are optionally combined to form a carbonyl group; and R¹ to R⁵ are each independently a linear, branched, or cyclic alkyl group having 1 to 12 carbon atoms, a linear, branched, or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, some or all of hydrogen atoms of these groups are optionally substituted with a hydroxy group, a carboxy group, a halogen atom, an oxo group, a cyano group, an amide group, a nitro group, a sultone group, a sulfone group, or a sulfonium salt-containing group, a part of the methylene group constituting these groups is optionally substituted with an ether group, an ester group, a carbonyl group, a carbonate group, or a sulfonic acid ester group, and R¹ and R² are optionally bonded to form a ring together with a sulfur atom to which R¹ and R² are bonded.)

A resist material containing a base resin containing a polymer having a repeating unit represented by the following formula (a).

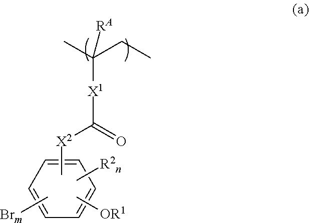

(In formula (a), R^{A} is a hydrogen atom or a methyl group, R¹ is a hydrogen atom or an acid-unstable group, R² is a linear, branched or cyclic alkyl group having 1 to 6 carbon atoms or a halogen atom other than bromine, X¹ is a single bond or a phenylene group, or a linear, branched or cyclic alkylene group having 1 to 12 carbon atoms, which optionally contains an ester group or a lactone ring, X² is —O—, —O—CH₂—, or —NH—, m is an integer of 1 to 4, and u is an integer of 0 to 3, provided that m+u is an integer of 1 to 4.)

A resist composition which generates an acid by exposure and whose solubility in a developer is changed by an action of an acid, the resist composition containing:

a base material component (A) whose solubility in a developer is changed by an action of an acid; and a fluorine additive component (F) which exhibits decomposability in an alkaline developer,
wherein the fluorine additive component (F) contains a fluororesin component (F1) having a structural unit (f1) containing a base-dissociable group and a structural unit (f2) containing a group represented by the following general formula (f2-r-1).

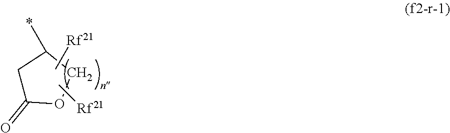

[In formula (f2-r-1), Rf²¹ is each independently a hydrogen atom, an alkyl group, an alkoxy group, a hydroxyl group, a hydroxyalkyl group, or a cyano group, n″ is an integer of 0 to 2, and * is a bond.]

The structural unit (f1) includes a structural unit represented by the following general formula (f1-1) or a structural unit represented by the following general formula (f1-2).

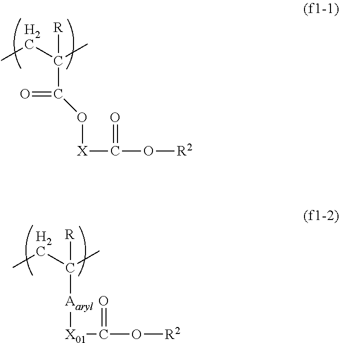

[In formulas (f1-1) and (f1-2), R each independently represents a hydrogen atom, an alkyl group having 1 to 5 carbon atoms, or a halogenated alkyl group having 1 to 5 carbon atoms, X represents a divalent linking group having no acid-dissociable site, A_{aryl} represents a divalent aromatic cyclic group optionally having a substituent, X₀₁ represents a single bond or a divalent linking group, and R² each independently represent an organic group having a fluorine atom.]

Examples of the coating, the coating solution, and the coating composition include the following.

A coating containing a metal oxo-hydroxo network having organic ligands by a metal carbon bond and/or a metal carboxylate bond.

An inorganic oxo/hydroxo-based composition.

A coating solution containing: an organic solvent; a first organometallic composition represented by the formula R_{z}SnO_{(2-(z/2)-(x/2)}(OH)ₓ (where 0<z≤2 and 0<(z+x)≤4), the formula R′ₙSnX₄₋ₙ (where n=1 or 2), or a mixture thereof, wherein R and R′ are independently a hydrocarbyl group having 1 to 31 carbon atoms, and X is a ligand having a hydrolysable bond to Sn or a combination thereof; and a hydrolyzable metal compound represented by the formula MX′v (where M is a metal selected from Group 2 to 16 of the periodic table of the elements, v is a number of 2 to 6, and X′ is a ligand having a hydrolysable M-X bond or a combination thereof).

A coating solution containing: an organic solvent; and a first organometallic compound represented by the formula RSnO_{(3/2-x/2)}(OH)ₓ (where 0<x<3), wherein the solution contains about 0.0025 M to about 1.5 M of tin, R is an alkyl or cycloalkyl group having 3 to 31 carbon atoms, and the alkyl or cycloalkyl group is bonded to tin via a secondary or tertiary carbon atom.

An inorganic pattern forming precursor aqueous solution containing a mixture of water, a metal suboxide cation, a polyatomic inorganic anion, and a radiation-sensitive ligand containing a peroxide group.

The irradiation with EB or EUV is performed, for example, through a mask (reticle) for forming a predetermined pattern. The resist underlayer film of the present invention is applied for electron beam (EB) irradiation or extreme ultraviolet (EUV) irradiation (13.5 nm), but is preferably applied for extreme ultraviolet (EUV) exposure.

The irradiation energy of EB and the exposure amount of EUV are not particularly limited.

Post exposure bake (PEB) may be performed after irradiation with EB or EUV and before development.

The baking temperature is not particularly limited, but is preferably 60° C. to 150° C., more preferably 70° C. to 120° C., and particularly preferably 75° C. to 110° C.

The baking time is not particularly limited, but is preferably 1 second to 10 minutes, more preferably 10 seconds to 5 minutes, and particularly preferably 30 seconds to 3 minutes.

For the development, for example, an alkaline developer is used.

The development temperature is, for example, 5° C. to 50° C.

The developing time is, for example, 10 seconds to 300 seconds.

Examples of the alkaline developer that can be used include aqueous solutions of inorganic alkalis such as sodium hydroxide, potassium hydroxide, sodium carbonate, sodium silicate, sodium metasilicate, and ammonia water; first amines such as ethylamine and n-propylamine; second amines such as diethylamine and di-n-butylamine; third amines such as triethylamine and methyldiethylamine, alcoholamines such as dimethylethanolamine and triethanolamine; quaternary ammonium salts such as tetramethylammonium hydroxide, tetraethylammonium hydroxide, and choline; and cyclic amines such as pyrrole and piperidine. Furthermore, an appropriate amount of an alcohol such as isopropyl alcohol or a surfactant such as a nonionic surfactant may be added to an aqueous solution of the above-described alkali, and used. Among these, a preferred developer is an aqueous solution of a quaternary ammonium salt, more preferably an aqueous solution of tetramethylammonium hydroxide and an aqueous solution of choline. Furthermore, a surfactant or the like can be added to these developers. A method of performing development with an organic solvent such as butyl acetate in place of the alkaline developer, and developing a portion where the alkali dissolution rate of the photoresist is not improved can also be used.

Next, the resist underlayer film is etched using the formed resist pattern as a mask. The etching may be dry etching or wet etching, but is preferably dry etching.

When the inorganic film is formed on the surface of the used semiconductor substrate, the surface of the inorganic film is exposed. When the inorganic film is not formed on the surface of the used semiconductor substrate, the surface of the semiconductor substrate is exposed. Thereafter, the semiconductor device is produced through a step of processing the semiconductor substrate by a known method (dry etching method or the like).

### EXAMPLES

Next, the contents of the present invention will be specifically described with reference to Examples, but the present invention is not limited thereto.

The weight average molecular weights of the polymers shown in the following Synthesis Examples 1 to 8 and Comparative Synthesis Example 1 in the present specification are the measurement results by gel permeation chromatography (hereinafter, abbreviated as GPC). A GPC apparatus manufactured by Tosoh Corporation was used for the measurement, and measurement conditions and the like are as follows.
GPC column: TSKgel Super-MultiporeHZ-N (two columns)
Column temperature: 40° C.
Solvent: tetrahydrofuran (THF)
Flow rate: 0.35 ml/min
Standard sample: polystyrene (manufactured by Tosoh Corporation)

### Synthesis Example 1

In 32.00 g of propylene glycol monomethyl ether acetate, 5.68 g (molar ratio relative to the whole polymer 1: 75%) of 2-vinylnaphthalene, 1.60 g (molar ratio relative to the whole polymer 1: 25%) of 2-hydroxyethyl methacrylate, and 0.73 g of 2,2′-azobisisobutyronitrile were dissolved. A reaction vessel was purged with nitrogen, and then the solution was heated and stirred at 140° C. for about 4 hours. This reaction solution was added dropwise to isopropyl alcohol, and the precipitate was recovered by suction filtration, and then dried at 60° C. under reduced pressure to recover a polymer 1. The weight average molecular weight Mw measured by GPC in terms of polystyrene was 8,500. The structure present in the polymer 1 is represented by the following formula.

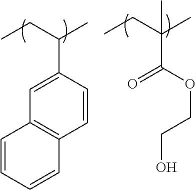

### Synthesis Example 2

In 40.00 g of propylene glycol monomethyl ether acetate, 4.75 g (molar ratio relative to the whole polymer 2: 55%) of 2-vinylnaphthalene, 2.96 g (molar ratio relative to the whole polymer 2: 30%) of benzyl methacrylate, 1.21 g (molar ratio relative to the whole polymer 2: 15%) of 2-hydroxypropyl methacrylate, and 1.07 g of 2,2′-azobisisobutyronitrile were dissolved. A reaction vessel was purged with nitrogen, and then the solution was heated and stirred at 140° C. for about 4 hours. This reaction solution was added dropwise to isopropyl alcohol, and the precipitate was recovered by suction filtration, and then dried at 60° C. under reduced pressure to recover a polymer 2. The weight average molecular weight Mw measured by GPC in terms of polystyrene was 5,900. The structure present in the polymer 2 is represented by the following formula.

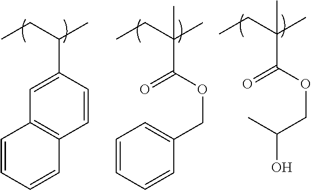

### Synthesis Example 3

In 97 g of cyclohexanone in a flask, 10.00 g (molar ratio relative to the whole polymer 3: 40%) of 2-vinylnaphthalene and 23.00 g (molar ratio relative to the whole polymer 3: 60%) of 3-hydroxy-2-adamantyl methacrylate were dissolved, and then the inside of the flask was purged with nitrogen, and the temperature was raised to 60° C. After the temperature was raised, a solution obtained by dissolving 1.60 g of 2,2′-azobisisobutyronitrile in 41.00 g of cyclohexanone was added dropwise, and the mixture was stirred for about 24 hours. The reaction solution was added dropwise to methanol, and the precipitate was recovered by suction filtration and then dried at 60° C. under reduced pressure to recover a polymer 3. The weight average molecular weight Mw measured by GPC in terms of polystyrene was 16,000. The structure present in the polymer 3 is represented by the following formula.

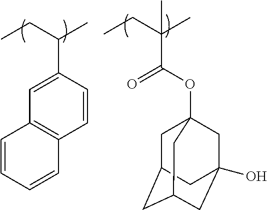

### Synthesis Example 4

In 95 g of cyclohexanone in a flask, 10.00 g (molar ratio relative to the whole polymer 4: 40%) of 2-vinylnaphthalene, 17.90 g (molar ratio relative to the whole polymer 4: 40%) of 9-anthracene methyl methacrylate, and 4.67 g (molar ratio relative to the whole polymer 4: 20%) of 2-hydroxyethyl methacrylate were dissolved, and then the inside of the flask was purged with nitrogen, and the temperature was raised to 60° C. After the temperature was raised, a solution obtained by dissolving 1.60 g of 2,2′-azobisisobutyronitrile in 41.00 g of cyclohexanone was added dropwise, and the mixture was stirred for about 24 hours. The reaction solution was added dropwise to methanol, and the precipitate was recovered by suction filtration and then dried at 60° C. under reduced pressure to recover a polymer 4. The weight average molecular weight Mw measured by GPC in terms of polystyrene was 8,000. The structure present in the polymer 4 is represented by the following formula.

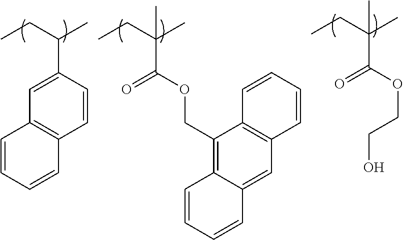

### Synthesis Example 5

In 24.00 g of propylene glycol monomethyl ether acetate, 2.94 g (molar ratio relative to the whole polymer 5: 50%) of 2-vinylnaphthalene, 1.24 g (molar ratio relative to the whole polymer 5: 25%) of hydroxyethyl methacrylate, 1.71 g (molar ratio relative to the whole polymer 5: 25%) of N-cyclohexylmaleimide, and 0.12 g of 2,2′-azobisisobutyronitrile were dissolved. A reaction vessel was purged with nitrogen, and then the solution was heated and stirred at 140° C. for about 4 hours. This reaction solution was added dropwise to isopropyl alcohol, and the precipitate was recovered by suction filtration, and then dried at 60° C. under reduced pressure to recover a polymer 5. The weight average molecular weight Mw measured by GPC in terms of polystyrene was 16, 300. The structure present in the polymer 5 is represented by the following formula.

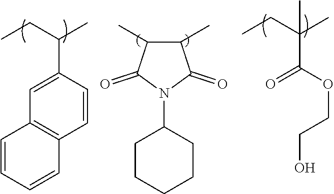

### Synthesis Example 6

In 24.00 g of propylene glycol monomethyl ether acetate, 2.86 g (molar ratio relative to the whole polymer 6: 50%) of 2-vinylnaphthalene, 1.68 g (molar ratio relative to the whole polymer 6: 25%) of N-cyclohexylmaleimide, 1.32 g (molar ratio relative to the whole polymer 6: 25%) of N-hydroxyethylmaleimide, and 0.12 g of 2,2′-azobisisobutyronitrile were dissolved. A reaction vessel was purged with nitrogen, and then the solution was heated and stirred at 140° C. for about 4 hours. This reaction solution was added dropwise to isopropyl alcohol, and the precipitate was recovered by suction filtration, and then dried at 60° C. under reduced pressure to recover a polymer 6. The weight average molecular weight Mw measured by GPC in terms of polystyrene was 11, 900. The structure present in the polymer 6 is represented by the following formula.

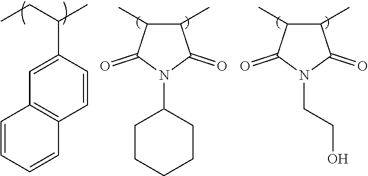

### Synthesis Example 7

To 167.27 g of propylene glycol monomethyl ether acetate in a flask, 50.00 g (molar ratio relative to the whole polymer 7: 67%) of N-phenyl-1-naphthylamine, 20.43 g (molar ratio relative to the whole polymer 7: 33%) of N-cyclohexylmaleimide, 21.91 g of methanesulfonic acid, and 1.26 g of hydroquinone were added, and then the mixture was stirred at 140° C. for 24 hours. The reaction solution was added dropwise to methanol, and the precipitate was recovered by suction filtration and then dried at 60° C. under reduced pressure to recover a polymer 7. The weight average molecular weight Mw measured by GPC in terms of polystyrene was 2,000. The structure present in the polymer 7 is represented by the following formula.

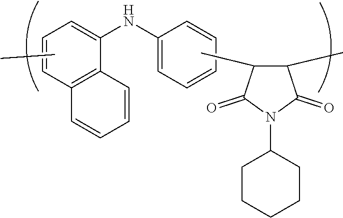

### Synthesis Example 8

To 54.91 g of propylene glycol monomethyl ether in a flask, 15.00 g (molar ratio relative to the whole polymer 8: 67%) of carbazole, 8.04 g (molar ratio relative to the whole polymer 8: 33%) of N-cyclohexylmaleimide, 8.62 g of methanesulfonic acid, and 0.49 g of hydroquinone were added, and then the mixture was stirred at 140° C. for 23 hours. The reaction solution was added dropwise to methanol, and the precipitate was recovered by suction filtration and then dried at 60° C. under reduced pressure to recover a polymer 8. The weight average molecular weight Mw measured by GPC in terms of polystyrene was 6,000. The structure present in the polymer 8 is represented by the following formula.

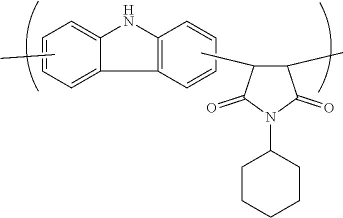

### Comparative Synthesis Example 1

To 682.00 g of propylene glycol monomethyl ether in a reaction vessel, 100.00 g of monoallyl diglycidyl isocyanuric acid (manufactured by Shikoku Chemicals Corporation), 66.4 g of 5,5-diethylbarbituric acid (manufactured by Tateyama Kasei Co., Ltd), and 4.1 g of benzyltriethylammonium chloride were added and dissolved. The reaction vessel was purged with nitrogen, and then the mixture was reacted at 130° C. for 24 hours to obtain a solution containing a comparative polymer 1. As a result of GPC analysis, the obtained comparative polymer 1 had a weight average molecular weight of 6,800 in terms of standard polystyrene, and a dispersity of 4.8. The structure present in the comparative polymer 1 is represented by the following formula.

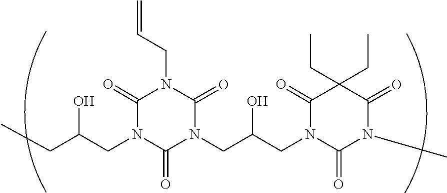

### (Preparation of Resist Underlayer Film-Forming Composition)

The components were mixed in the proportions shown in Table 1, and the mixture was filtered using a polyethylene microfilter having a pore size of 0.05 μm to thereby prepare resist underlayer film-forming compositions of Preparation Examples 1 to 8 and a resist underlayer film-forming composition of Comparative Preparation Example 1, respectively.

Abbreviations in Table 1 are as follows.
PyPSA: pyridinium-p-hydroxybenzenesulfonic acid
PGMEA: propylene glycol monomethyl ether acetate
PGME: propylene glycol monomethyl ether
PGME-PL: Imidazo[4,5-d]imidazole-2,5(1H,3H)-dione, tetrahydro-1, 3, 4, 6-tetrakis[(2-methoxy-1-methylethoxy)methyl] (the following structural formula)

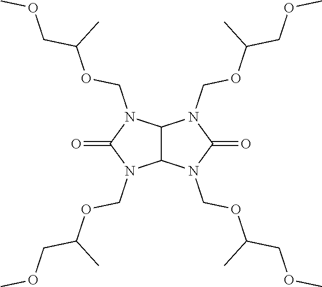

TMOM-BP: 3,3′,5,5′-tetrakis(methoxymethyl)-[1,1′-biphenyl]-4,4′-diol (trade name: TMOM-BP, manufactured by Honshu Chemical Industry Co., Ltd., substructural formula)

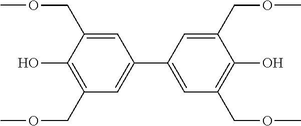

TABLE 1

| | | | Curing | | |
|---|---|---|---|---|---|
| | Component 1 | Component 2 | catalyst | Solvent | |
| Preparation | Polymer 1 | PGME-PL | PyPSA | PGME | PGMEA |
| Example 1 | | | | | |
| (part by mass) | 0.151 | 0.043 | 0.008 | 30 | 70 |
| Preparation | Polymer 2 | PGME-PL | PyPSA | PGME | PGMEA |
| Example 2 | | | | | |
| (part by mass) | 0.151 | 0.043 | 0.008 | 30 | 70 |
| Preparation | Polymer 3 | PGME-PL | PyPSA | PGME | PGMEA |
| Example 3 | | | | | |
| (part by mass) | 0.151 | 0.043 | 0.008 | 30 | 70 |
| Preparation | Polymer 4 | PGME-PL | PyPSA | PGME | PGMEA |
| Example 4 | | | | | |
| (part by mass) | 0.151 | 0.043 | 0.008 | 30 | 70 |
| Preparation | Polymer 5 | PGME-PL | PyPSA | PGME | PGMEA |
| Example 5 | | | | | |
| (part by mass) | 0.151 | 0.043 | 0.008 | 30 | 70 |
| Preparation | Polymer 6 | PGME-PL | PyPSA | PGME | PGMEA |
| Example 6 | | | | | |
| (part by mass) | 0.151 | 0.043 | 0.008 | 30 | 70 |
| Preparation | Polymer 7 | TMOM-BP | PyPSA | PGME | PGMEA |
| Example 7 | | | | | |
| (part by mass) | 0.138 | 0.048 | 0.006 | 50 | 50 |
| Preparation | Polymer 8 | TMOM-BP | PyPSA | PGME | PGMEA |
| Example 8 | | | | | |
| (part by mass) | 0.138 | 0.048 | 0.006 | 50 | 50 |
| Comparative | Comparative | PGME-PL | PyPSA | PGME | PGMEA |
| Preparation | Polymer 1 | | | | |
| Example 1 | | | | | |
| (part by mass) | 0.151 | 0.043 | 0.008 | 30 | 70 |

### (Preparation of Resist Underlayer Film)

### Examples 1 to 8 and Comparative Example 1

Each of the resist underlayer film-forming compositions of Preparation Examples 1 to 8 and Comparative Preparation Example 1 was applied onto a silicon wafer using a spinner. The silicon wafer was baked on a hot plate at 205 to 250° C. for 60 seconds to obtain resist underlayer films of Examples 1 to 8 and Comparative Example 1 each having a film thickness of 5 nm. The film thickness was measured using an ellipsometric film thickness measurement system RE-3100 (SCREEN Semiconductor Solutions Co., Ltd.).

A resist underlayer film of Example 1 was obtained using the resist underlayer film-forming composition of Preparation Example 1.

A resist underlayer film of Example 2 was obtained using the resist underlayer film-forming composition of Preparation Example 2.

A resist underlayer film of Example 3 was obtained using the resist underlayer film-forming composition of Preparation Example 3.

A resist underlayer film of Example 4 was obtained using the resist underlayer film-forming composition of Preparation Example 4.

A resist underlayer film of Example 5 was obtained using the resist underlayer film-forming composition of Preparation Example 5.

A resist underlayer film of Example 6 was obtained using the resist underlayer film-forming composition of Preparation Example 6.

A resist underlayer film of Example 7 was obtained using the resist underlayer film-forming composition of Preparation Example 7.

A resist underlayer film of Example 8 was obtained using the resist underlayer film-forming composition of Preparation Example 8.

A resist underlayer film of Comparative Example 1 was obtained using the resist underlayer film-forming composition of Comparative Preparation Example 1.

### (Evaluation of Resist Patterning)

### <Test for Resist Pattern Formation by Electron Beam Lithography Apparatus>

An EUV positive resist solution was spin-coated on each of the resist underlayer films of Examples 1 to 8 and Comparative Example 1 formed on a silicon wafer, and heated at 130° C. for 60 seconds to form an EUV resist film having a film thickness of 35 nm. The resist film was exposed under a predetermined condition using an electron beam lithography apparatus (ELS-G130). After the exposure, the silicon wafer was baked (PEB) at 90° C. for 60 seconds, cooled on a cooling plate to room temperature, and subjected to puddle developing for 30 seconds using a 2.38% aqueous tetramethylammonium hydroxide solution (trade name NMD-3 manufactured by Tokyo Ohka Kogyo Co., Ltd.) as a photoresist developer. A resist pattern having a line size of 16 nm to 28 nm was formed. A scanning electron microscope (CG4100, manufactured by Hitachi High-Tech Corporation) was used for measuring the length of the resist pattern.

The photoresist pattern thus obtained was observed from the upper part of the pattern. The amount of charge for forming 22 nm line/44 nm pitch (line-and-space (L/S=1/1)) was defined as the optimum irradiation energy, and the irradiation energy (μC/cm²) at that time and LWR which is a value indicating the roughness of the pattern shape were confirmed. The LWR indicates a triple value (30) (unit: nm) of a standard deviation (o) obtained from the measurement results at 400 line positions in the longitudinal direction of the line with a scanning electron microscope (CG4100, manufactured by Hitachi High-Tech Corporation). A smaller value of LWR indicates that a favorable pattern is formed. The results are shown in Table 2.

As Comparative Example 2, the same test was also conducted for the case of using a substrate prepared by subjecting a silicon substrate to hexamethyldisilazane (HMDS) treatment without forming a resist underlayer film. The results are shown in Table 2.

TABLE 2

| | Irradiation | |
|---|---|---|
| | energy | LWR |
| | (μC/cm²) | (nm) |
| Example 1 | 455 | 3.24 |
| Example 2 | 472 | 3.20 |
| Example 3 | 456 | 3.35 |
| Example 4 | 469 | 3.20 |
| Example 5 | 440 | 3.25 |
| Example 6 | 445 | 3.25 |
| Example 7 | 545 | 3.37 |
| Example 8 | 509 | 3.24 |
| Comparative | 464 | 3.49 |
| Example 1 | | |
| Comparative | 447 | 3.63 |
| Example 2 | | |

In Examples 1 to 8, improvement in LWR was confirmed as compared with Comparative Examples 1 and 2. Note that, when a resist underlayer film having a film thickness of 20 nm or more is used, the film thickness of the resist film is thin in the dry etching step after formation of the resist pattern. Therefore, the resist pattern is damaged in the process of etching the underlayer film to cause shape defects such as a decrease in the resist film thickness or a top rounding shape, thus making it difficult to form a pattern having a target line width when the substrate is actually processed.

1. A resist underlayer film which is a baked product of a coating film of a resist underlayer film-forming composition,
the resist underlayer film-forming composition containing a polymer having at least one unit structure of a unit structure (A) having a polycyclic aromatic hydrocarbon structure, and a unit structure (B) derived from a maleimide structure, and
the resist underlayer film having a film thickness of less than 10 nm.

2. The resist underlayer film according to claim 1, wherein the polycyclic aromatic hydrocarbon structure in the unit structure (A) includes at least one structure selected from the group consisting of naphthalene, anthracene, phenanthrene, carbazole, pyrene, triphenylene, chrysene, naphthacene, biphenylene, and fluorene.

3. The resist underlayer film according to claim 1, wherein the unit structure (B) is represented by the following formula (4): 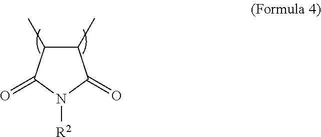
wherein R² represents a hydrogen atom, an alkyl group having 1 to 10 carbon atoms, which is optionally substituted with a hydroxy group, or an aryl group having 6 to 10 carbon atoms, which is optionally substituted with a halogen atom.

4. The resist underlayer film according to claim 1, wherein the polymer further has a unit structure (C) having a cross-linkable group.

5. The resist underlayer film according to claim 4, wherein the cross-linkable group in the unit structure (C) includes at least one group selected from the group consisting of a hydroxy group, an epoxy group, a protected hydroxy group, and a protected carboxy group.

6. The resist underlayer film according to claim 1, wherein the resist underlayer film-forming composition further contains a crosslinking agent.

7. The resist underlayer film according to claim 1, wherein the resist underlayer film-forming composition further contains a curing catalyst.

8. The resist underlayer film according to claim 1, which is a resist underlayer film for EB or EUV lithography.

9. A resist underlayer film-forming composition for EB or EUV lithography, comprising a polymer having at least one unit structure of a unit structure (A) having a polycyclic aromatic hydrocarbon structure and a unit structure (B) having a maleimide structure.

10. The resist underlayer film-forming composition for EB or EUV lithography according to claim 9, wherein the polycyclic aromatic hydrocarbon structure in the unit structure (A) includes at least one structure selected from the group consisting of naphthalene, anthracene, phenanthrene, carbazole, pyrene, triphenylene, chrysene, naphthacene, biphenylene, and fluorene.

11. The resist underlayer film-forming composition for EB or EUV lithography according to claim 9, wherein the unit structure (B) is represented by the following formula (4): 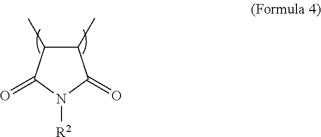
wherein R² represents a hydrogen atom, an alkyl group having 1 to 10 carbon atoms, which is optionally substituted with a hydroxy group, or an aryl group having 6 to 10 carbon atoms, which is optionally substituted with a halogen atom.

12. The resist underlayer film-forming composition for EB or EUV lithography according to claim 9, wherein the polymer further has a unit structure (C) having a cross-linkable group.

13. The resist underlayer film-forming composition for EB or EUV lithography according to claim 12, wherein the cross-linkable group in the unit structure (C) includes at least one group selected from the group consisting of a hydroxy group, an epoxy group, a protected hydroxy group, and a protected carboxy group.

14. The resist underlayer film-forming composition for EB or EUV lithography according to claim 9, further comprising a crosslinking agent.

15. The resist underlayer film-forming composition for EB or EUV lithography according to claim 9, further comprising a curing catalyst.

16. (canceled)

17. A resist underlayer film for EB or EUV lithography, which is a baked product of a coating film of the resist underlayer film-forming composition for EB or EUV lithography according to claim 9.

18. A semiconductor processing substrate comprising:
a semiconductor substrate; and
the resist underlayer film according to claim 1.

19. A method for producing a semiconductor element, comprising:
forming a resist underlayer film having a film thickness of less than 10 nm on a semiconductor substrate using the resist underlayer film-forming composition for EB or EUV lithography according to claim 9; and
forming a resist film on the resist underlayer film using a resist for EB or EUV lithography.

20. A method for forming a pattern, comprising:
forming a resist underlayer film having a film thickness of less than 10 nm on a semiconductor substrate using the resist underlayer film-forming composition for EB or EUV lithography according to claim 9;
forming a resist film on the resist underlayer film using a resist for EB or EUV lithography;
irradiating the resist film with EB or EUV, and then developing the resist film to obtain a resist pattern; and
etching the resist underlayer film using the resist pattern as a mask.

21. A method for improving LWR of a resist pattern, comprising:
forming a resist underlayer film having a film thickness of less than 10 nm on a semiconductor substrate using the resist underlayer film-forming composition for EB or EUV lithography according to claim 9;
forming a resist film on the resist underlayer film using a resist for EB or EUV lithography; and
irradiating the resist film with EB or EUV, and then developing the resist film to obtain a resist pattern.
